(19) United States
(12) Patent Application Publication
(10) Pub. No.: US 2025/0120279 A1
(43) Pub. Date: Apr. 10, 2025

(54) LIGHT PATH CONTROL MEMBER AND DISPLAY DEVICE COMPRISING SAME

(71) Applicant: LG INNOTEK CO., LTD., Seoul (KR)

(72) Inventors: Jun LEE, Seoul (KR); Byung Sook KIM, Seoul (KR); Jin Gyeong PARK, Seoul (KR)

(21) Appl. No.: 18/729,587

(22) PCT Filed: Dec. 14, 2022
(86) PCT No.: PCT/KR2022/020343

§ 371 Date: Jul. 17, 2024

(30) Foreign Application Priority Data
Jan. 17, 2022 (KR) 10-2022-0006834

(51) Int. Cl. H10K 59/38; H10K 59/80

(52) U.S. Cl. CPC H10K 59/38; H10K 59/875

(57) ABSTRACT

A light path control member according to an embodiment includes a first substrate; a first electrode disposed on the first substrate; a buffer layer disposed on the first electrode; a second substrate disposed on the first substrate; a second electrode disposed under the second substrate; a light conversion part disposed between the first electrode and the second electrode; an adhesive layer disposed between the second electrode and the light conversion part; and a sealing part disposed in a cutting region penetrating the second substrate, the second electrode, and the adhesive layer.

### TECHNICAL FIELD

An embodiment relates to a light path control member and a display device including the same.

### BACKGROUND ART

A light blocking film is a film that blocks light from being transmitted from a light source. The light blocking film is attached to a front of a display panel, which is a display device used for a mobile phone, laptop, tablet PC, vehicle navigation, or vehicle touch screen. The light blocking film adjusts a viewing angle of light according to an angle of incidence of light when the display outputs a screen. As a result, the user can view clear image quality at the desired viewing angle.

In addition, light blocking film is used for windows in vehicles or buildings. In detail, the light blocking film can prevent glare by partially shielding external light. Alternatively, the light blocking film can make an inside invisible from an outside.

That is, the light blocking film controls a movement path of light. As a result, the light blocking film can block light at an angle within a set range and transmit light at an angle within a set range. Accordingly, a transmission angle of light is controlled by the light blocking film.

The light blocking film can be divided into a light blocking film that can always control the viewing angle regardless of the surrounding environment, and a switchable light blocking film that allows the user to turn the viewing angle control on and off depending on the surrounding environment.

The switchable light blocking film includes a light conversion part including a receiving part. The receiving part is filled with a light conversion material including particles and a dispersion liquid for dispersing the particles. The particles can move by application of voltage. The receiving part may be converted into a light transmitting part and a light blocking part by dispersion and aggregation of the particles.

An adhesive layer may be partially disposed on the light blocking film to bond the layer structure of the light blocking film. However, the adhesive layer has a very low moisture vapor transmission rate. Accordingly, moisture may penetrate into the light blocking film through the adhesive layer.

When moisture penetrates into the light blocking film, defects in appearance can occur. In addition, a dielectric constant of a region where moisture has penetrated and a dielectric constant of the area where moisture has not penetrated in the receiving part may change. As a result, a difference in driving speed of each receiving part may occur.

Accordingly, a light path control member with a new structure that can solve the above problems is required.

### DISCLOSURE

### Technical Problem

An embodiment provides a light path control member capable of blocking moisture that may be introduced into an inside using an adhesive layer.

### Technical Solution

A light path control member according to an embodiment includes a first substrate; a first electrode disposed on the first substrate; a buffer layer disposed on the first electrode; a second substrate disposed on the first substrate; a second electrode disposed under the second substrate; a light conversion part disposed between the first electrode and the second electrode; an adhesive layer disposed between the second electrode and the light conversion part; and a sealing part disposed in a cutting region penetrating the second substrate, the second electrode, and the adhesive layer.

### ADVANTAGEOUS EFFECTS

The light path control member according to an embodiment includes a cutting region. A sealing part is disposed in the cutting region. The adhesive layer may be partially removed through the cutting region. Accordingly, the adhesive layer has a spaced portion formed in a region where the sealing part is disposed.

The sealing part is disposed on the spaced portion. Accordingly, the light path control member may prevent moisture penetrating from an outside from moving into the receiving part along the adhesive layer.

That is, the moisture moving along the adhesive layer is blocked by the sealing part disposed in the spaced portion. Therefore, it is possible to prevent the moisture from penetrating into the receiving part.

The light path control member according to an embodiment may prevent moisture from penetrating into the receiving part. Thereby, it is possible to prevent the light conversion material and the moisture from being mixed. Accordingly, it is possible to prevent a decrease in the driving characteristics of the light path control member according to an embodiment. In addition, the light path control member according to an embodiment may have improved reliability.

### DESCRIPTION OF DRAWINGS

FIG. 1 is a perspective view of a light path control member according to a first embodiment.

FIGS. 2 and 3 are views for explaining a direction of a receiving part of the light path control member according to a first embodiment.

FIGS. 4 and 5 are views illustrating a cross-sectional view taken along the A-A′ region of FIG. 1.

FIGS. 6 and 7 are views illustrating a cross-sectional view taken along the B-B′ region of FIG. 3.

FIGS. 8 and 9 are views illustrating a cross-sectional view taken along the C-C′ region of FIG. 3.

FIG. 10 is a perspective view of the light path control member according to a second embodiment.

FIGS. 11 and 12 are views illustrating a cross-sectional view taken along the D-D′ region of FIG. 10.

FIGS. 13 and 14 are views illustrating a cross-sectional view taken along the E-E′ region of FIG. 10.

FIGS. 15 and 16 are cross-sectional views of a display device to which a light path control member according to an embodiment is applied.

FIGS. 17 to 19 are views for explaining an embodiment of a display device to which an light path control member according to an embodiment is applied.

### BEST MODE

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a light path control member according to an embodiment will be described with reference to the drawings. The light path control member described hereinafter may be a switchable light blocking film that is driven in a share mode or a light blocking mode according to an application of power.

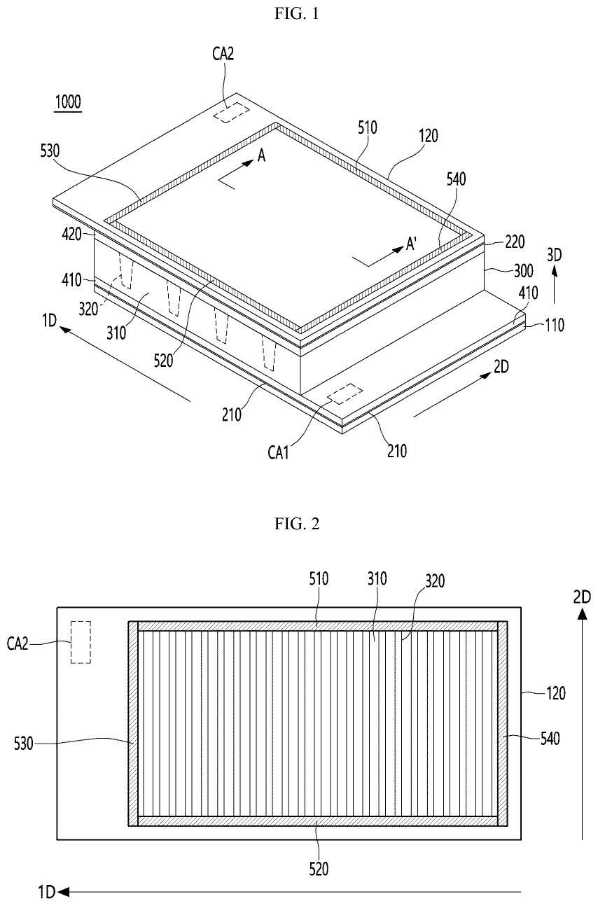

FIG. 1 is a perspective view of a light path control member according to an embodiment.

The light path control member may extend in a first direction 1D, a second direction 2D, and a third direction 3D.

Specifically, the first direction 1D and the second direction 2D may correspond to a longitudinal direction or a width direction of the light path control member. In addition, the first direction 1D and the second direction 2D may be different directions. Also, the third direction 3D may correspond to a thickness direction of the light path control member.

Hereinafter, for convenience of explanation, the first direction 1D is defined in the longitudinal direction of the light path control member. Furthermore, the second direction 2D is defined in the width direction of the light path control member. Furthermore, the third direction 3D is defined in the thickness direction of the light path control member.

Referring to FIG. 1, the light path control member 1000 according to an embodiment includes a first substrate 110, a second substrate 120, a first electrode 210, a second electrode 220, and a light conversion part 300.

The first substrate 110 and the second substrate 120 may be rigid or flexible.

In addition, the first substrate 110 and the second substrate 120 may be transparent. For example, the first substrate 110 and the second substrate 120 may include a transparent substrate capable of transmitting light.

The first substrate 110 and the second substrate 120 may include glass, plastic, or a flexible polymer film. For example, the flexible polymer film may include any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), Triacetylcellulose (TAC), polyvinyl alcohol (PVA) film, polyimide (PI), or polystyrene (PS).

In addition, the first substrate 110 and the second substrate 120 may be a flexible substrate with flexible characteristics.

Also, the first substrate 110 and the second substrate 120 may be curved or bent. Therefore, the light path control member may also have flexible, curved, or bent characteristics. Accordingly, the light path control member may be formed in various designs.

The first substrate 110 and the second substrate 120 may have a thickness within a predetermined range. For example, thicknesses of the first substrate 110 and the second substrate 120 may be in a range of 30 μm to 100 μm. Specifically, the thicknesses of the first substrate 110 and the second substrate 120 may be in a range of 40 μm to 80 μm. More specifically, the thicknesses of the first substrate 110 and the second substrate 120 may be in a range of 50 μm to 60 μm.

When the thicknesses of the first substrate 110 and the second substrate 120 exceed 100 μm, the overall thickness and weight of the light path control member may be increased.

In addition, when the thicknesses of the first substrate 110 and the second substrate 120 are less than 30 μm, a support force of the first substrate 110 and the second substrate 120 may be reduced.

Thicknesses of the first substrate 110 and the second substrate 120 may be the same or similar within the set range.

The first electrode 210 and the second electrode 220 may include a transparent conductive material. For example, the first electrode 210 and the second electrode 220 may include a conductive material having a light transmittance of about 80% or more. For example, the first electrode 210 and the second electrode 220 may include a metal oxide such as indium tin oxide, indium zinc oxide, copper oxide, tin oxide, zinc oxide, titanium oxide and the like.

Alternatively, the first electrode 210 and the second electrode 220 may include various metals to realize low resistance. For example, the first electrode 210 and the second electrode 220 may include at least one metal among chromium (Cr), nickel (Ni), copper (Cu), aluminum (Al), silver (Ag), molybdenum (Mo). Gold (Au), titanium (Ti), and alloys thereof.

The first electrode 210 and the second electrode 220 may have a thickness within a predetermined range. For example, the thicknesses of the first electrode 210 and the second electrode 220 may be 0.2 μm to 1 μm. Specifically, the thicknesses of the first electrode 210 and the second electrode 220 may be 0.2 μm to 0.5 μm.

When the thicknesses of the first electrode 210 and the second electrode 220 exceed 1 μm, the overall thickness and weight of the light path control member may be increased.

Also, when the thicknesses of the first electrode 210 and the second electrode 220 are less than 0.2 μm, conductivity of the first electrode 210 and the second electrode 220 may be reduced. Accordingly, driving characteristics of the light path control member may be reduced.

Thicknesses of the first electrode 210 and the second electrode 220 may be the same or similar within the set range.

Connection electrodes may be disposed on each of the first substrate 110 and the second substrate 120. In detail, a first connection electrode CA1 may be disposed on the first substrate 110. The first connection electrode CA1 may be formed by exposing the first electrode 210. Also, a second connection electrode CA2 may be disposed on the second substrate 120. The second connection electrode CA2 may be formed by exposing the second electrode 220.

The light path control member may be electrically connected to an external (flexible) printed circuit board by the first connection electrode CA1 and the second connection region CA2.

For example, a pad part may be disposed on the first connection electrode CA1 and the second connection electrode CA2. A conductive adhesive including an anisotropic conductive film (ACF) or anisotropic conductive paste (ACP) may be disposed between the pad part and the (flexible) printed circuit board. Accordingly, the light path control member may be electrically connected to an external (flexible) printed circuit board.

Alternatively, a conductive adhesive including an anisotropic conductive film (ACF) or anisotropic conductive paste (ACP) is disposed between the first connection electrode CA1 and the second connection electrode CA2 and the (flexible) printed circuit board. That is, the pad part may be omitted. Accordingly, the light path control member may be directly connected to an external (flexible) printed circuit board.

The light conversion part 300 may be disposed between the first substrate 110 and the second substrate 120. Specifically, the light conversion part 300 may be disposed between the first electrode 210 and the second electrode 220.

A buffer layer 410 may be disposed between the light conversion part 300 and the first electrode 210. Adhesive force between the first electrode 220 and the light conversion part 300 may be improved by the buffer layer 410. That is, the buffer layer 410 may be a primer layer disposed between the light conversion part 300 and the first electrode 210.

An adhesive layer 420 may be disposed between the light conversion part 300 and the second electrode 220. The light conversion part and the second electrode 220 may be adhered by the adhesive layer 420.

The buffer layer 410 and the adhesive layer 420 may include a transparent material through which light may be transmitted. For example, the buffer layer 410 may include a transparent resin. Also, the adhesive layer 420 may include a light transparent adhesive (OCA).

The adhesive layer 420 is disposed on the light conversion part 300. A pressure may be applied when the light conversion part 300 and the second electrode 220 are adhered. The adhesive layer 420 may be introduced into the receiving part 320 of the light conversion part 300 by the pressure. Accordingly, the adhesive layer 420 may be partially disposed inside a receiving part 320.

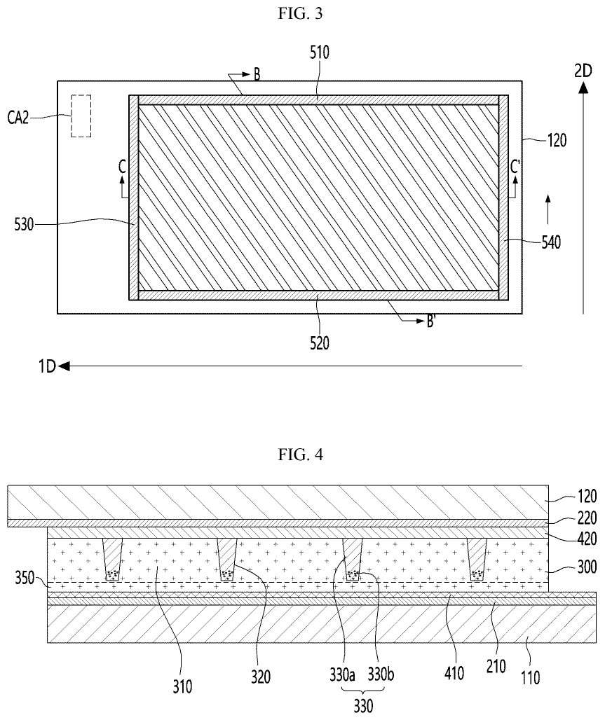

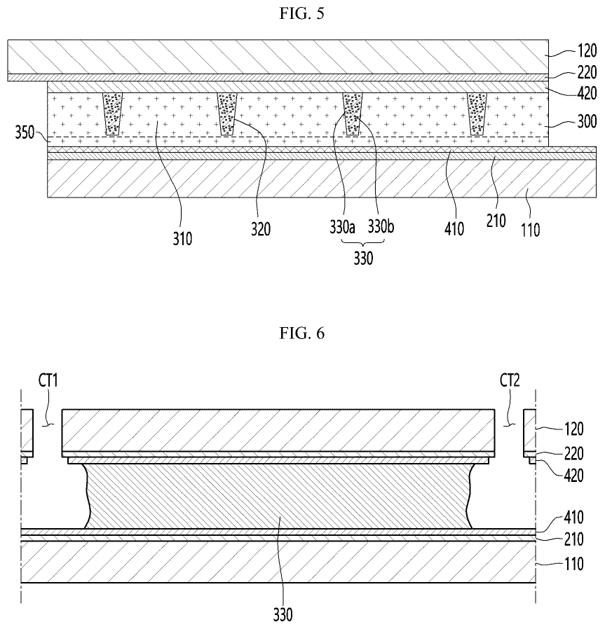

FIGS. 2 and 3 are views for explaining a direction of a receiving part of the light path control member according to a first embodiment, FIGS. 4 and 5 are views illustrating a cross-sectional view taken along the A-A′ region of FIG. 1, and FIGS. 4 and 5 are enlarged views of the region of FIG. 2.

Referring to FIGS. 2 to 5, the light conversion part 300 may include a plurality of partition wall parts 310, a plurality of receiving parts 320, and a base part 350.

The partition wall part 310 and the receiving part 320 may be alternately disposed. That is, one receiving part 320 is disposed between two adjacent partition wall parts 310. Also, one partition wall part 310 may be disposed between two adjacent receiving parts 320.

The receiving part 320 is tilted at an inclination angle within a range set with respect to the first direction 1D and the second direction 2D. Accordingly, when the light path control member and the display panel are combined to form a display device, a moiré phenomenon caused by overlapping the receiving part and a pattern part of the display panel may be prevented.

The base part 350 may be disposed under the receiving part 320. Specifically, the base part 350 may be disposed between the receiving part 320 and the buffer layer 410. More specifically, the base part 350 may be disposed between a lower surface of the receiving part 320 and an upper surface of the buffer layer 510. Accordingly, the light conversion part 300 and the first electrode 210 may be adhered by the base part 350 and the buffer layer 410.

The base part 350 may be disposed under the receiving part 320. Specifically, the base part 350 may be disposed between the receiving part 320 and the buffer layer 410. More specifically, the base part 350 may be disposed between a lower surface of the receiving part 320 and an upper surface of the buffer layer 510. Accordingly, the light conversion part 300 and the first electrode 210 may be adhered by the base part 350 and the buffer layer 410.

Also, an adhesive layer 420 may be disposed between the partition wall part 310 and the second electrode 220. The light conversion part 300 and the second electrode 220 may be adhered by the adhesive layer 420.

The base part 350 is a region formed when the resin material used to form the partition wall part 310 and the receiving part 320 is released from a mold member. Accordingly, the base part 350 may include the same material as the partition wall part 310. That is, the base part 350 and the partition wall part 310 may be integrally formed.

The partition wall part 310 may transmit light. Also, the light transmittance of the receiving part 320 may be changed by the application of a voltage.

Specifically, the light conversion material 330 may be disposed in the receiving part 320. The light conversion material 330 may be sealed by sealing parts 510, 520, 530, and 540. For example, when the receiving part 320 extends in the second direction 2D as shown in FIG. 2, the light conversion material 330 may be sealed by the first sealing part 510 and the second sealing part 520.

Alternatively, when the receiving part 320 is tilted and disposed as shown in FIG. 3, the light conversion material 330 may be sealed by the first sealing part 510, the second sealing part 520, the third sealing part 530, and the fourth sealing part 540.

The light transmittance of the receiving part 320 may be changed by the light conversion material 330. The light conversion material 330 may include light conversion particles 330b and a dispersion liquid 330a. The light conversion particles 330b may move by the application of a voltage. Also, the dispersion liquid 330a may disperse the light conversion particles 330b. Also, the light conversion material 300 may further include a dispersant preventing aggregation of the light conversion particles 330b.

When a voltage is applied, the light conversion particles 330b may be moved. For example, referring to FIG. 4, surfaces of the light conversion particles 330b are charged with negative charges. When the first electrode 210 and the second electrode 220 apply a positive voltage, the light conversion particles 330b are moved toward the first electrode 210 or the second electrode 220. Accordingly, the receiving part 320 may become a light transmitting part.

Also, referring to FIG. 5, a negative voltage may be applied to the first electrode 210 and the second electrode 220. Accordingly, the light conversion particles 330b are dispersed again into the dispersion liquid 330a. Accordingly, the receiving part 320 may be a light blocking part.

As described above, the adhesive layer 420 may be disposed between the light conversion part 300 and the second electrode 220. Also, the adhesive layer 420 may adhere the light conversion part 300 and the second electrode 220. Accordingly, the adhesive layer 420 may be exposed on an outer surface of the light path control member.

A water vapor transmission rate of the material forming the adhesive layer 420 is smaller than that of other layers. Therefore, external moisture may be introduced into the light path control member through the adhesive layer 420. That is, the moisture may be introduced into the receiving part 320 along an adhesive layer having low moisture permeability.

Accordingly, the light path control member according to an embodiment may cut a region of the adhesive layer to prevent inflow of moisture.

Referring to FIGS. 6 to 9, the light path control member may include a plurality of cutting regions. In detail, the light path control member may include a first cutting region CT1, a second cutting region CT2, a third cutting region CT3, and a fourth cutting region CT4.

A first cutting region CT1 may be defined as a region in which the first sealing part 510 is disposed. Also, a second cutting region CT2 may be defined as a region in which the second sealing part 520 is disposed. Also, a third cutting region CT3 may be defined as a region in which the third sealing part 530 is disposed. Also, a fourth cutting region CT4 may be defined as a region in which the fourth sealing part 540 is disposed.

The first cutting region CT1 may be an injection portion into which the light conversion material 330 is injected. The second cutting region CT2 may be a suction portion into which the light conversion material 330 is injected.

Accordingly, the light conversion material 330 may be filled in the receiving part 320. Subsequently, the first cutting region CT1 and the second cutting region CT2 may be filled with a sealing material and cured, respectively. Accordingly, the first sealing part 510 and the second sealing part 520 may be disposed in the first cutting region CT1 and the second cutting region CT2, respectively.

Also, the third cutting region CT3 and the fourth cutting region CT4 may be regions for forming the light path control member to have a desired size. That is, the third cutting region CT3 and the fourth cutting region CT4 may be formed after filling the inside of the receiving part 320 with the light conversion material 330. Subsequently, the third cutting region CT3 and the fourth cutting region CT4 may be filled with a sealing material and cured. Accordingly, the third cutting region CT3 and the fourth cutting region CT4 may be disposed with a third sealing part 530 and a fourth sealing part 540 respectively.

The cutting regions CT1, CT2, CT3, and CT4 may be formed by partially penetrating the light path control member. Specifically, the cutting regions CT1, CT2, CT3, and CT4 may be formed by penetrating the second substrate 120, the second electrode 220, and the adhesive layer 420.

Accordingly, the second substrate 120, the second electrode 220, and the adhesive layer 420 may be removed from a region in which the cutting regions CT1, CT2, CT3, and CT4 are formed. That is, the adhesive layer 420 may be partially removed from a region in which the cutting regions CT1, CT2, CT3, and CT4 are formed.

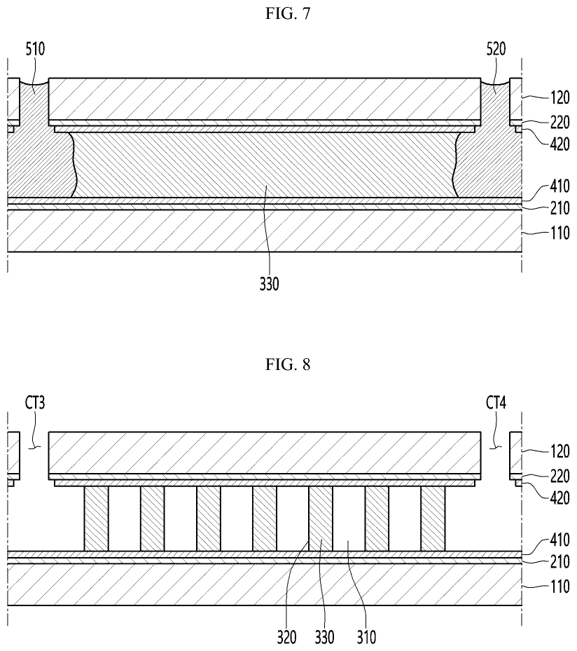

FIGS. 6 and 7 are views for explaining a first sealing part 510 and a second sealing part 520 of the light path control member according to an embodiment. FIG. 6 is a view before a sealing part is disposed in the cutting region. FIG. 7 is a view after a sealing part is disposed in the cutting region.

Referring to FIGS. 6 and 7, the light path control member may include a first cutting region CT1 and a second cutting region CT1.

The first cutting region CT1 and the second cutting region CT2 may be formed by removing the second substrate 120, the second electrode 220, and the adhesive layer 420.

Accordingly, the adhesive layer 420 may be spaced apart from each other by the first cutting region CT1 and the second cutting region CT2. Accordingly, a side surface of the adhesive layer 420 may be exposed by the first cutting region CT1 and the second cutting region CT2.

The first cutting region CT1 and the second cutting region CT2 may be filled with a sealing material. Accordingly, the first sealing part 510 and the second sealing part 520 may be disposed in the first cutting region CT1 and the second cutting region CT2. Accordingly, the sealing material may be disposed in a separation region of the adhesive layer 420. That is, the first sealing part 510 and the second sealing part 520 may be disposed in the separation region of the adhesive layer 420.

Specifically, the first sealing part 510 and the second sealing part 520 may fill a portion where the adhesive layer 420 is spaced apart from each other. Also, the first sealing part 510 and the second sealing part 520 may be in contact with a side surface and a lower surface of the adhesive layer 420.

That is, the first sealing part 510 and the second sealing part 520 may be in contact with the light conversion material 330 inside the receiving part 320. Accordingly, the light conversion material 330 may be sealed inside the receiving part 320.

Furthermore, the first sealing part 510 and the second sealing part 520 may be disposed inside the separation region of the adhesive layer 420 in the receiving part 320. Furthermore, the first sealing part 510 and the second sealing part 520 may be in contact with the side surface and the lower surface of the adhesive layer 420. Accordingly, the sealing part may be disposed in the separation region of the adhesive layer 420. Therefore, moisture moving along the adhesive layer 420 may be blocked by the sealing parts 510 and 520.

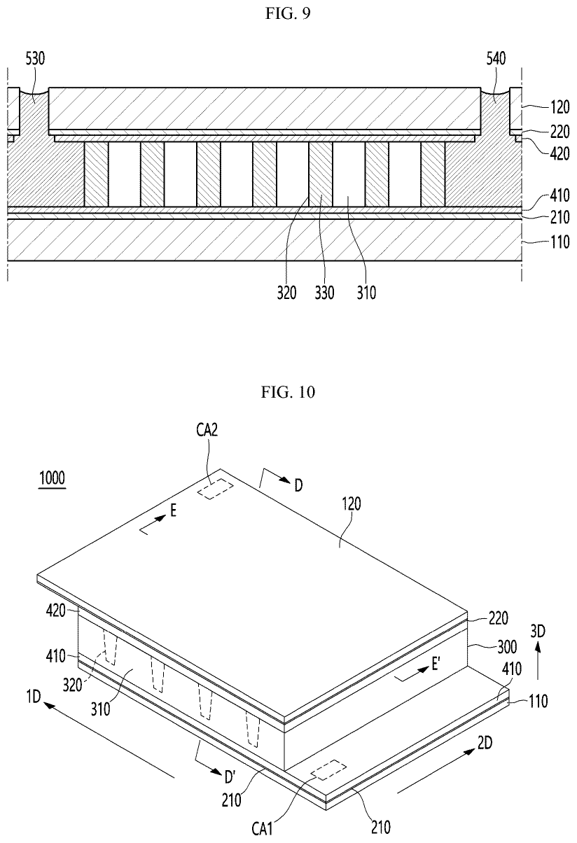

FIGS. 8 and 9 are views for explaining a third sealing part 510 and a fourth sealing part 540 of the light path control member according to an embodiment. FIG. 8 is a view before a sealing part is disposed in the cutting region. FIG. 9 is a view after a sealing part is disposed in the cutting region.

Referring to FIGS. 8 and 9, the light path control member may include a third cutting region CT3 and a fourth cutting region CT4.

The third cutting region CT3 and the fourth cutting region CT4 may be formed by removing the second substrate 120, the second electrode 220, and the adhesive layer 420.

Accordingly, the adhesive layer 420 may be spaced apart from each other by the third and fourth cutting regions CT3 and CT4. Accordingly, a side surface of the adhesive layer 420 may be exposed by the third and fourth cutting regions CT3 and CT4.

The third cutting region CT3 and the fourth cutting region CT4 may be filled with a sealing material. Accordingly, the third sealing part 530 and the fourth sealing part 540 may be disposed in the third cutting region CT3 and the fourth cutting region CT4. Accordingly, the sealing material may be disposed in the separation region of the adhesive layer 420. That is, the third sealing part 530 and the fourth sealing part 540 may be disposed in the separation region of the adhesive layer 420.

Specifically, the third sealing part 530 and the fourth sealing part 540 may fill a portion where the adhesive layer 420 is spaced apart from each other. Also, the third sealing part 530 and the fourth sealing part 540 may be in contact with the side surface and the lower surface of the adhesive layer 420.

That is, the third sealing part 530 and the fourth sealing part 540 are in contact with the upper surface of the partition wall 310, the side surface and the lower surface of the adhesive layer 420.

The third sealing part 530 and the fourth sealing part 540 are disposed in the separation region of the adhesive layer 420. Also, the third sealing part 530 and the fourth sealing part 540 are disposed in contact with the side surface and the lower surface of the adhesive layer. Accordingly, the sealing part may be disposed in the separation region of the adhesive layer 420. Accordingly, moisture moving along the adhesive layer 420 may be blocked by the sealing parts 530 and 540.

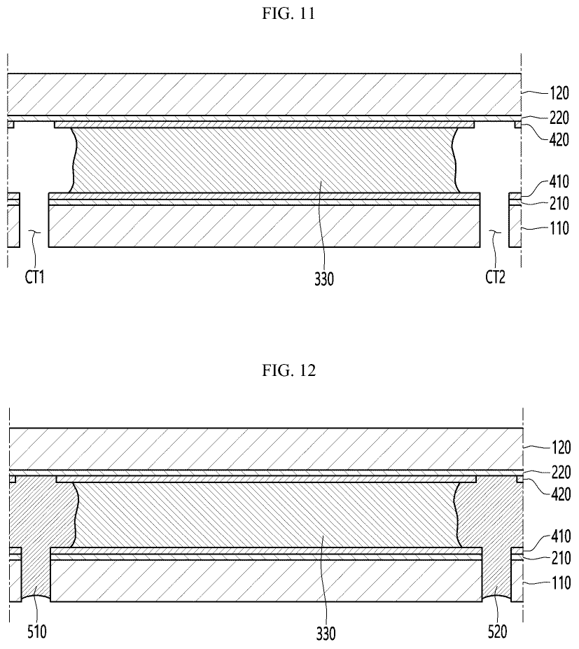

Hereinafter, a light path control member according to a second embodiment will be described with reference to FIGS. 10 to 14. In the description of the light path control member according to the second embodiment, a description of the same configuration as the configuration of the optical path control member according to the first embodiment described above will be omitted. Also, the same reference numerals are assigned to the same configuration.

Referring to FIGS. 10 to 14, the light path control member according to the second embodiment may include a plurality of cutting regions and sealing parts.

The light path control member according to the second embodiment may have a different position of the cutting region from the light path control member according to the first embodiment described above. Accordingly, a position of the sealing part may also be different.

Referring to FIGS. 11 and 12, the light path control member according to the second embodiment may include a first cutting region CT1 and a second cutting region CT2.

The first cutting region CT1 and the second cutting region CT2 may be formed by removing the first substrate 110, the first electrode 210, the buffer layer 410, the light conversion part 300, and the adhesive layer 420.

Accordingly, the adhesive layer 420 may be spaced apart from each other by the first cutting region CT1 and the second cutting region CT2. Accordingly, the side surface of the adhesive layer 420 may be exposed by the first cutting region CT1 and the second cutting region CT2.

The first cutting region CT1 and the second cutting region CT2 may be filled with a sealing material. Accordingly, the first sealing part 510 and the second sealing part 520 may be disposed in the first cutting region CT1 and the second cutting region CT2. Accordingly, the sealing material may be disposed in the separation region of the adhesive layer 420. That is, the first sealing part 510 and the second sealing part 520 may be disposed in the separation region of the adhesive layer 420.

Specifically, the first sealing part 510 and the second sealing part 520 may fill a portion where the adhesive layer 420 is spaced apart from each other. Also, the first sealing part 510 and the second sealing part 520 may be in contact with the side surface and the lower surface of the adhesive layer 420.

That is, the first sealing part 510 and the second sealing part 520 are in contact with the light conversion material 330 inside the receiving part 320. Accordingly, the light conversion material 330 may be sealed inside the receiving part 320.

Also, the first sealing part 510 and the second sealing part 520 may be disposed inside the separation region of the adhesive layer 420 in the receiving part 320. Also, the first sealing part 510 and the second sealing part 520 may be in contact with the side surface and the lower surface of the adhesive layer. Accordingly, the sealing part is disposed in the separation region of the adhesive layer 420. Therefore, moisture moving along the adhesive layer 420 may be blocked by the sealing parts 510 and 520.

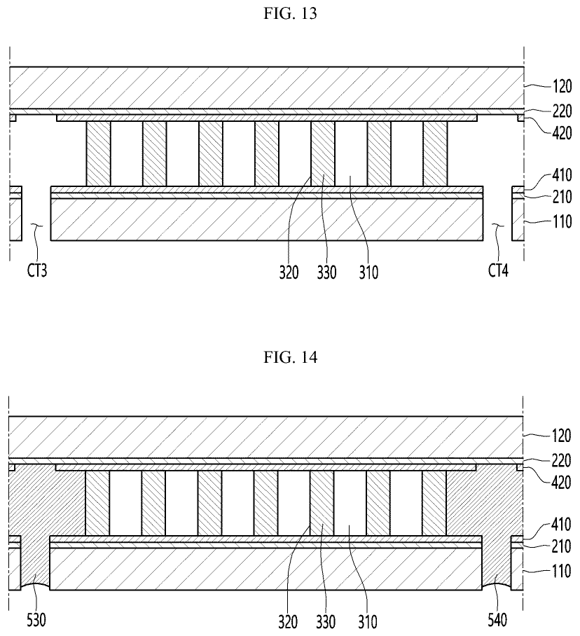

FIGS. 13 and 14 are views for explaining a third sealing part 510 and a fourth sealing part 540 of the light path control member according to a second embodiment. FIG. 13 is a view before a sealing part is disposed in the cutting region. FIG. 14 is a view after a sealing part is disposed in the cutting region.

Referring to FIGS. 13 and 14, the light path control member may include a third cutting region CT3 and a fourth cutting region CT4.

The third cutting region CT3 and the fourth cutting region CT4 may be formed by removing the first substrate 110, the first electrode 210, the buffer layer 410, the light conversion part 300, and the adhesive layer 420.

Accordingly, the adhesive layer 420 may be spaced apart from each other by the third and fourth cutting regions CT3 and CT4. Accordingly, the side surface of the adhesive layer 420 may be exposed by the third and fourth cutting regions CT3 and CT4.

The third cutting region CT3 and the fourth cutting region CT4 may be filled with a sealing material. Accordingly, the third sealing part 530 and the fourth sealing part 540 may be disposed in the third cutting region CT3 and the fourth cutting region CT4. Accordingly, the sealing material may be disposed in the separation region of the adhesive layer 420. That is, the third sealing part 530 and the fourth sealing part 540 may be disposed in the separation region of the adhesive layer 420.

Specifically, the third sealing part 530 and the fourth sealing part 540 may fill a portion where the adhesive layer 420 is spaced apart from each other. Also, the third sealing part 530 and the fourth sealing part 540 may be disposed in contact with the side surface and the lower surface of the adhesive layer 420.

That is, the third sealing part 530 and the fourth sealing part 540 are in contact with the upper surface of the partition wall part 310, the side surface, and the lower surface of the adhesive layer 420.

The third sealing part 530 and the fourth sealing part 540 may be disposed in the separation region of the adhesive layer 420. Also, the third sealing part 530 and the fourth sealing part 540 may be disposed in contact with the side and lower surfaces of the adhesive layer. Accordingly, the sealing part may be disposed in the separation region of the adhesive layer 420. Therefore, moisture moving along the adhesive layer 420 may be blocked by the sealing parts 530 and 540.

The light path control member according to an embodiment includes a cutting region. A sealing part is disposed in the cutting region. The adhesive layer may be partially removed through the cutting region. Accordingly, the adhesive layer has a spaced portion formed in a region where the sealing part is disposed.

The sealing part is disposed on the spaced portion. Accordingly, the light path control member may prevent moisture penetrating from an outside from moving into the receiving part along the adhesive layer.

That is, the moisture moving along the adhesive layer is blocked by the sealing part disposed in the spaced portion. Therefore, it is possible to prevent the moisture from penetrating into the receiving part.

The light path control member according to an embodiment may prevent moisture from penetrating into the receiving part. Thereby, it is possible to prevent the light conversion material and the moisture from being mixed. Accordingly, it is possible to prevent a decrease in the driving characteristics of the light path control member according to an embodiment. In addition, the light path control member according to an embodiment may have improved reliability.

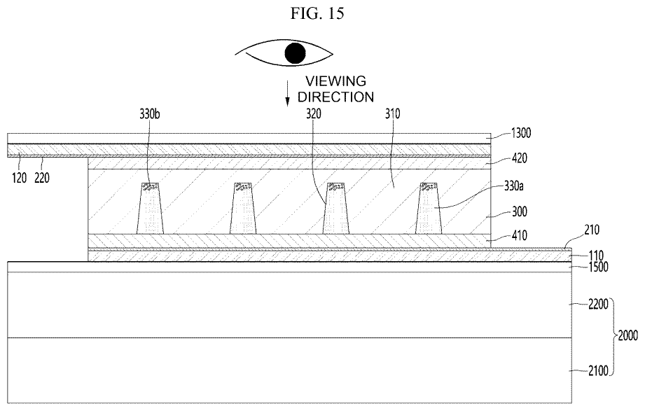

Hereinafter, a display device and a display device to which a light path control member according to an embodiment is applied will be described with reference to FIGS. 15 to 19.

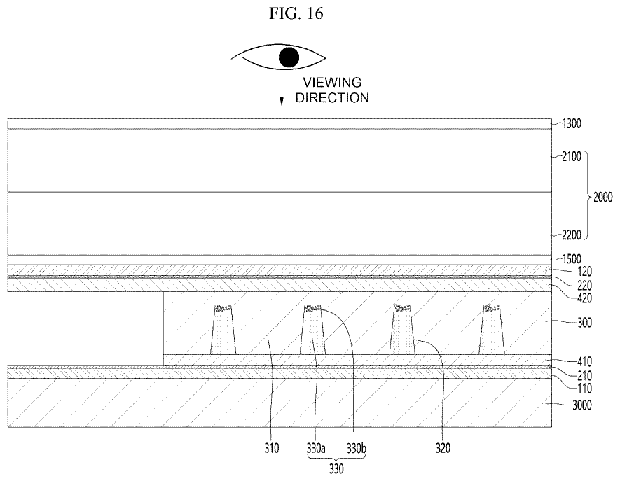

Referring to FIGS. 15 and 16, the light path control member 1000 according to the embodiment may be disposed on or below the display panel 2000.

The display panel 2000 and the light path control member 1000 may be disposed to be adhered to each other. For example, the display panel 2000 and the light path control member 1000 may be adhered to each other via an adhesive member 1500. The adhesive member 1500 may be transparent. For example, the adhesive member 1500 may include an adhesive or an adhesive layer including a light transparent adhesive material.

The adhesive member 1500 may include a release film. In detail, when adhering the light path control member and the display panel, the light path control member and the display panel may be adhered after the release film is removed.

The display panel 2000 may include a first base substrate 2100 and a second base substrate 2200. When the display panel 2000 is a liquid crystal display panel, the light path control member may be formed under the liquid crystal panel. That is, when a surface viewed by the user in the liquid crystal panel is defined as an upper portion of the liquid crystal panel, the light path control member may be disposed under the liquid crystal panel. The display panel 2000 may be formed in a structure in which the first base substrate 2100 including a thin film transistor (TFT) and a pixel electrode and the second base substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first base substrate 2100 and the second base substrate 2200 is bonded to the first base substrate 2100 with the liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 16, the light path control member may be disposed under the liquid crystal panel and on the backlight unit 3000, and the light path control member may be disposed between the backlight unit 3000 and the display panel 2000.

Alternatively, as shown in FIG. 15, when the display panel 2000 is an organic light emitting diode panel, the light path control member may be formed on the organic light emitting diode panel. That is, when the surface viewed by the user in the organic light emitting diode panel is defined as an upper portion of the organic light emitting diode panel, the light path control member may be disposed on the organic light emitting diode panel. The display panel 2000 may include a self-luminous element that does not require a separate light source. In the display panel 2000, a thin film transistor may be formed on the first base substrate 2100, and an organic light emitting element in contact with the thin film transistor may be formed. The organic light emitting element may include an anode, a cathode, and an organic light emitting layer formed between the anode and the cathode. In addition, the second base substrate 2200 configured to function as an encapsulation substrate for encapsulation may be further included on the organic light emitting element.

In addition, although not shown in drawings, a polarizing plate may be further disposed between the light path control member 1000 and the display panel 2000. The polarizing plate may be a linear polarizing plate or an external light reflection preventive polarizing plate. For example, when the display panel 2000 is a liquid crystal display panel, the polarizing plate may be a linear polarizing plate. Further, when the display panel 2000 is the organic light emitting diode panel, the polarizing plate may be an external light reflection preventing polarizing plate.

In addition, an additional functional layer 1300 such as an anti-reflection layer, an anti-glare, or the like may be further disposed on the light path control member 1000. Specifically, the functional layer 1300 may be adhered to one surface of the first substrate 110 of the light path control member. Although not shown in drawings, the functional layer 1300 may be adhered to the first substrate 110 of the light path control member via an adhesive layer. In addition, a release film for protecting the functional layer may be further disposed on the functional layer 1300.

Further, a touch panel may be further disposed between the display panel and the light path control member.

It is shown in the drawings that the light path control member is disposed at an upper portion of the display panel, but the embodiment is not limited thereto, and the light path control member may be disposed at various positions such as a position in which light is adjustable, that is, a lower portion of the display panel, or between a second substrate and a first substrate of the display panel, or the like.

In addition, it is shown in the drawings that the light conversion part of the light path control member according to the embodiment is in a direction parallel or perpendicular to an outer surface of the second substrate, but the light conversion part is formed to be inclined at a predetermined angle from the outer surface of the second substrate. Through this, a moiré phenomenon occurring between the display panel and the light path control member may be reduced.

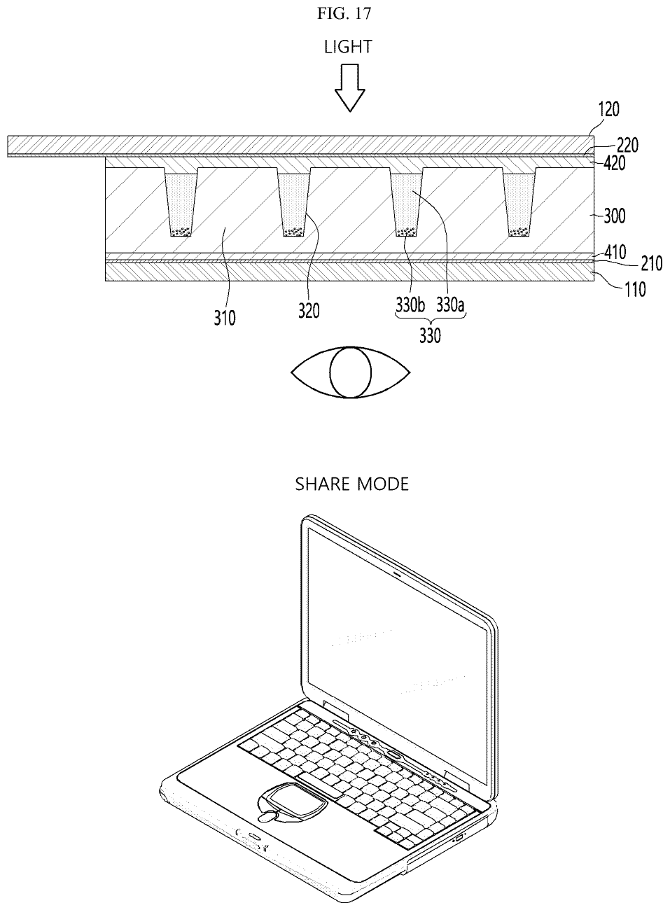

Referring to FIGS. 17 to 19, the light path control member according to the embodiment may be applied to a display device that displays a display.

Referring to FIGS. 17 to 19, the light path control member according to an embodiment may be applied to a display device that displays a display.

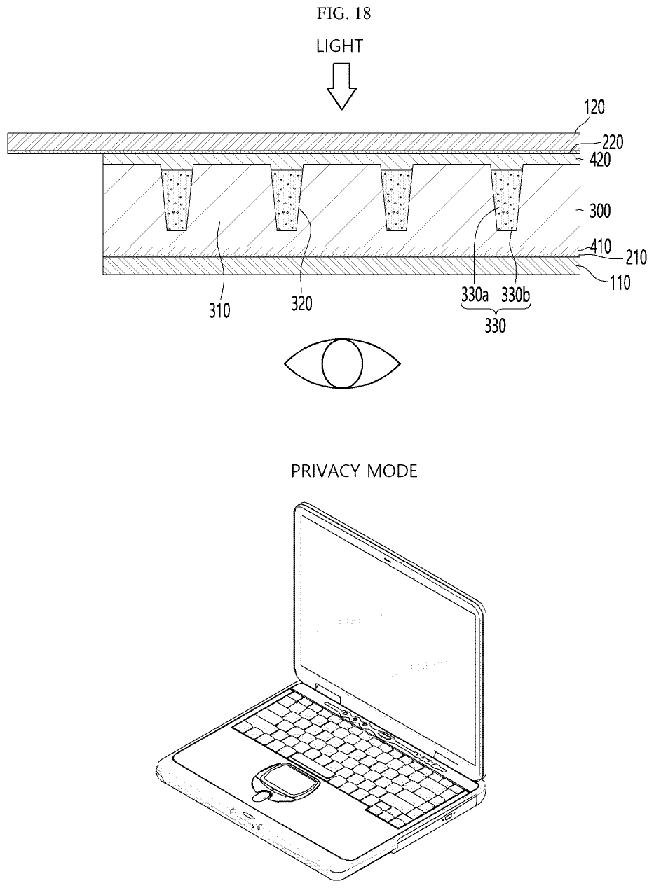

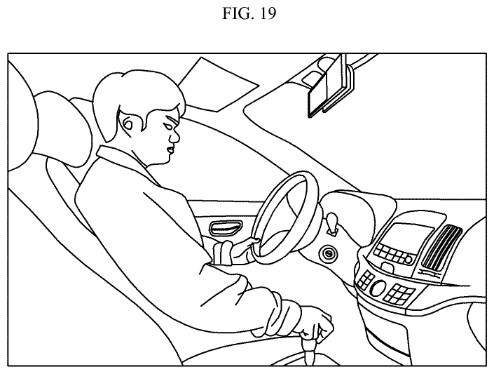

For example, when power is applied to the light path control member as shown in FIG. 17, the receiving part functions as the light transmitting part, so that the display device may be driven in the public mode, and when power is not applied to the light path control member as shown in FIG. 18, the receiving part functions as the light blocking part, so that the display device may be driven in the light blocking mode.

Accordingly, a user may easily drive the display device in a privacy mode or a normal mode according to application of power.

Light emitted from the backlight part or the self-luminous element may move from the first substrate toward the second substrate. Alternatively, the light emitted from the backlight part or the self-luminous element may also move from the second substrate toward the first substrate.

In addition, referring to FIG. 19, the display device to which the light path control member according to the embodiment is applied may also be applied inside a vehicle.

For example, the display device including the light path control member according to the embodiment may display a video confirming information of the vehicle and a movement route of the vehicle. The display device may be disposed between a driver seat and a passenger seat of the vehicle.

In addition, the light path control member according to the embodiment may be applied to a dashboard that displays a speed, an engine, an alarm signal, and the like of the vehicle.

Further, the light path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A light path control member comprising:
a first substrate;
a first electrode disposed on the first substrate;
a buffer layer disposed on the first electrode;
a second substrate disposed on the first substrate;
a second electrode disposed under the second substrate;
a light conversion part disposed between the first electrode and the second electrode;
an adhesive layer disposed between the second electrode and the light conversion part; and
a sealing part disposed in a cutting region penetrating the second substrate, the second electrode, and the adhesive layer,
wherein the sealing part includes a first portion penetrating the second substrate or the second electrode, and a second portion penetrating the adhesive layer, and
wherein the first portion and the second portion have different widths.

2. The light path control member of claim 1, wherein the light conversion part includes a plurality of receiving parts in which a light conversion material is disposed and a partition wall part disposed between the receiving parts,
wherein the sealing part includes a third portion penetrating the receiving parts, and
wherein the third portion of the sealing part is disposed on an upper surface of the partition wall part and inside the receiving parts.

3. The light path control member of claim 2, wherein the third portion of the sealing part is disposed inside the receiving parts to be in contact with the light conversion material and a side surface and a lower surface of the adhesive layer.

4. The light path control member of claim 1, wherein the sealing part is disposed in contact with side surfaces of the second substrate and the second electrode.

5. The light path control member of claim 1, wherein the sealing part includes:
a first sealing part and a second sealing part extending in a first direction and facing in a second direction different from the first direction; and
a third sealing part and a fourth sealing part extending in the second direction and facing in the first direction.

6. A light path control member comprising:
a first substrate;
a first electrode disposed on the first substrate;
a buffer layer disposed on the first electrode;
a second substrate disposed on the first substrate;
a second electrode disposed under the second substrate;
a light conversion part disposed between the first electrode and the second electrode;
an adhesive layer disposed between the second electrode and the light conversion part; and
a sealing part disposed in a cutting region penetrating the first substrate, the first electrode, the buffer layer, the light conversion part, and the adhesive layer,
wherein the sealing part includes a first portion penetrating at least one of the first substrate, the first electrode, or the buffer layer, and a second portion penetrating the adhesive layer, and
wherein the first portion and the second portion have different widths.

7. The light path control member of claim 6, wherein the light conversion part includes a plurality of receiving parts in which a light conversion material is disposed and a partition wall part disposed between the receiving parts, and
wherein the sealing part includes a third portion penetrating the receiving parts.

8. The light path control member of claim 7, wherein the third portion of the sealing part is in contact with the light conversion material and a bottom surface of the adhesive layer.

9. The light path control member of claim 6, wherein the second portion of the sealing part is disposed in contact with a bottom surface of the second electrode.

10. The light path control member of claim 6, wherein the sealing part includes:
a first sealing part and a second sealing part extending in a first direction and facing in a second direction different from the first direction; and
a third sealing part and a fourth sealing part extending in the second direction and facing in the first direction.

11. The light path control member of claim 2, wherein a width of the second portion of the sealing part is greater than that of the first portion of the sealing part.

12. The light path control member of claim 11, wherein a width of the third portion of the sealing part is greater than that of each of the first portion and the second portion of the sealing part.

13. The light path control member of claim 5, wherein a length of the first sealing part in the first direction is the same as a length of the second sealing part in the first direction.

14. The light path control member of claim 13, wherein each of the first sealing part and the second sealing part is located inside the outer surface of the optical conversion part.

15. The light path control member of claim 5, wherein a length of the third sealing part in the second direction is same as a length of the fourth sealing part in the second direction.

16. The light path control member of claim 15, wherein each of the third sealing part and the fourth sealing part is located inside the outer surface of the optical conversion part.

17. The light path control member of claim 1, wherein an upper surface of the first portion of the sealing part is concave toward a lower surface of the first portion.

18. The light path control member of claim 7, wherein a width of the second portion of the sealing part is greater than that of the first portion of the sealing part.

19. The light path control member of claim 18, wherein a width of the third portion of the sealing part is greater than that of each of the first portion and the second portion of the sealing part.

20. The light path control member of claim 10, wherein a length of the first sealing part in the first direction is same as a length of the second sealing part in the first direction, and,
wherein a length of the third sealing part in the second direction is same as a length of the fourth sealing part in the second direction.
